(19) United States
(12) Patent Application Publication
(10) Pub. No.: US 2015/0035481 A1
(43) Pub. Date: Feb. 5, 2015

(54) NON-CONTACT POWER TRANSMISSION DEVICE, MAGNETIC INDUCTION-TYPE POWER SUPPLY DEVICE, MAGNETIC INDUCTION-TYPE POWER COLLECTOR, AND MOVING OBJECT USING SAME

(71) Applicants: Dong Ho Cho, Seoul (KR); Seong Jeub Jeon, Busan (KR); Gu Ho Jung, Daejeon (KR); Kyung Hun Lee, Daejeon (KR); Hyung Kook Kim, Daejeon (KR); Seok Hwan Lee, Daejeon (KR); Sun Jong Lee, Daejeon (KR); Bo Yune Song, Seoul (KR); Byung O. Kong, Busan (KR); Joo Young Choi, Daejeon (KR); Jae Gue Shin, Daejeon (KR); Sung Jun Son, Jeonju (KR); Dae Won Seo, Daejeon (KR); Jin Hyuk Jang, Daejeon (KR)

(72) Inventors: Dong Ho Cho, Seoul (KR); Seong Jeub Jeon, Busan (KR); Gu Ho Jung, Daejeon (KR); Kyung Hun Lee, Daejeon (KR); Hyung Kook Kim, Daejeon (KR); Seok Hwan Lee, Daejeon (KR); Sun Jong Lee, Daejeon (KR); Bo Yune Song, Seoul (KR); Byung O. Kong, Busan (KR); Joo Young Choi, Daejeon (KR); Jae Gue Shin, Daejeon (KR); Sung Jun Son, Jeonju (KR); Dae Won Seo, Daejeon (KR); Jin Hyuk Jang, Daejeon (KR)

(73) Assignee: Korea Advanced Institute of Science and Technology, Daejeon (KR)

(21) Appl. No.: 13/878,993

(22) PCT Filed: Oct. 11, 2011
(86) PCT No.: PCT/KR2011/007530

§ 371 Date: Mar. 14, 2014

(30) Foreign Application Priority Data
Oct. 13, 2010 (KR) 10-2010-0100010

(51) Int. Cl. B60L 11/18; H02J 7/02; G01R 33/02; H01F 38/14

(52) U.S. Cl. CPC B60L 11/182; H01F 38/14; H02J 7/025; G01R 33/02; B60L 2210/30; B60L 2200/36
USPC 320/108

(57) ABSTRACT

Embodiments of the present invention relate to a non-contact power transmission device, a magnetic induction-type power supply device, a magnetic induction-type power collector, and a moving object using same. Embodiments of the present invention provide a non-contact power transmission device, a magnetic induction-type power supply device, a magnetic induction-type power collector, and a moving object using same, the non-contact power transmission device comprising: a power collector having a power collector core, and a boob power collector cable that winds around the power collector core; and a power supply unit comprising a power supply core having a holder section and protrusions on the center portion of the holder section and around the perimeter of the holder section, and a power supply cable wound in such a manner that electric currents flow in two different directions with respect to the protruding center portion, wherein the power collector is located in the opposite direction from the protruding portion.

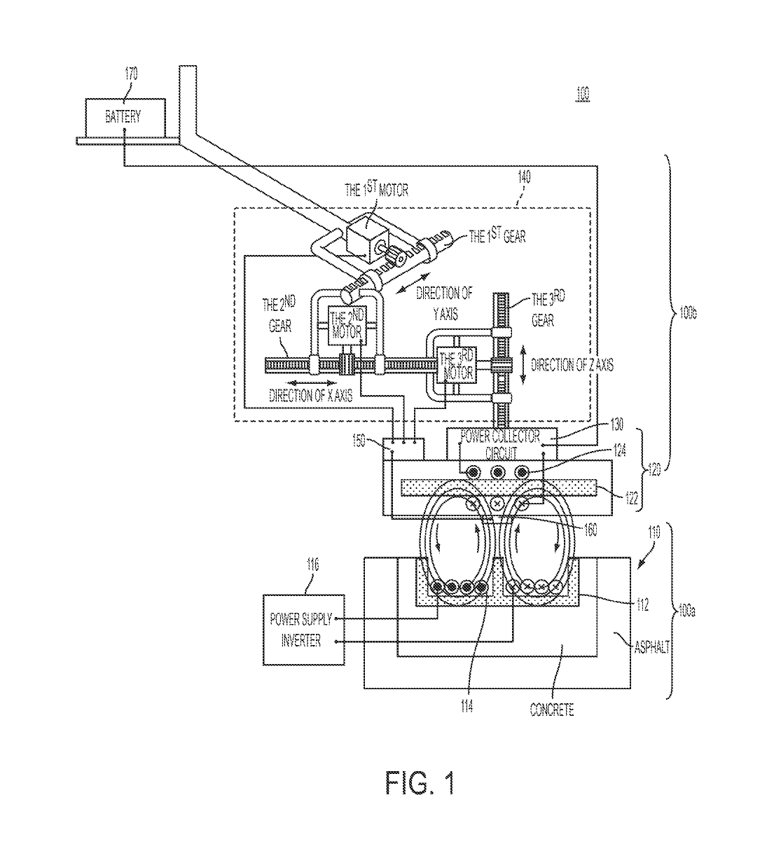

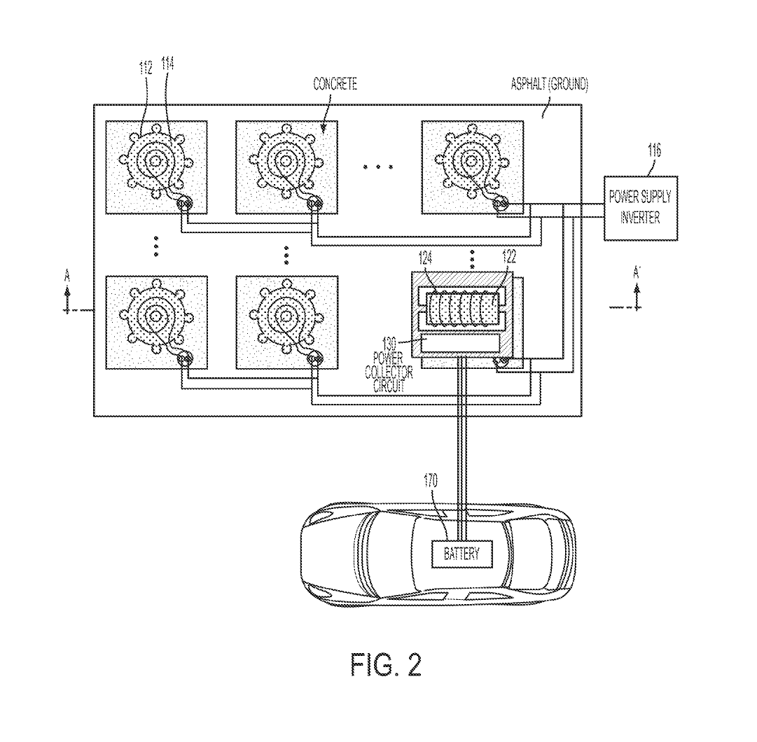

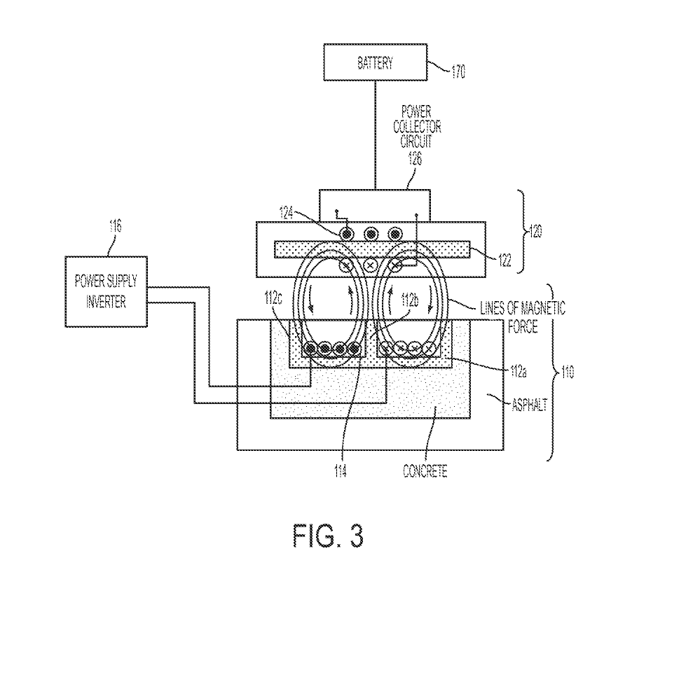

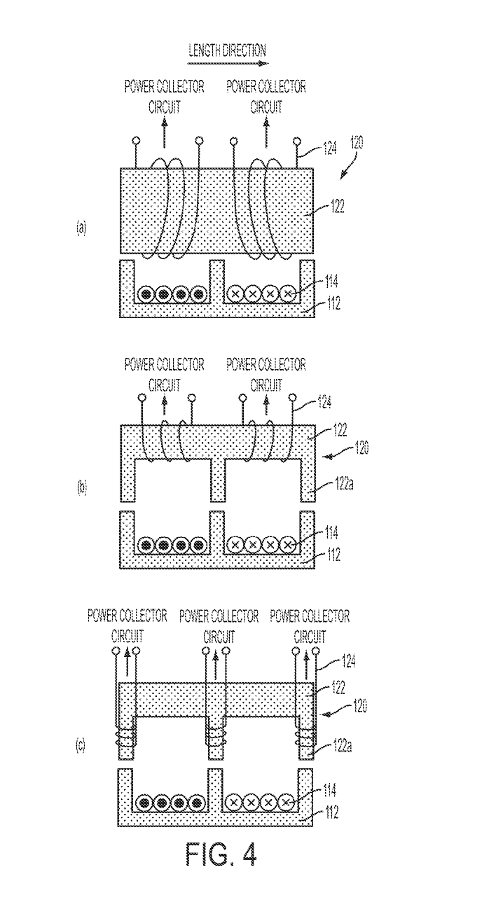

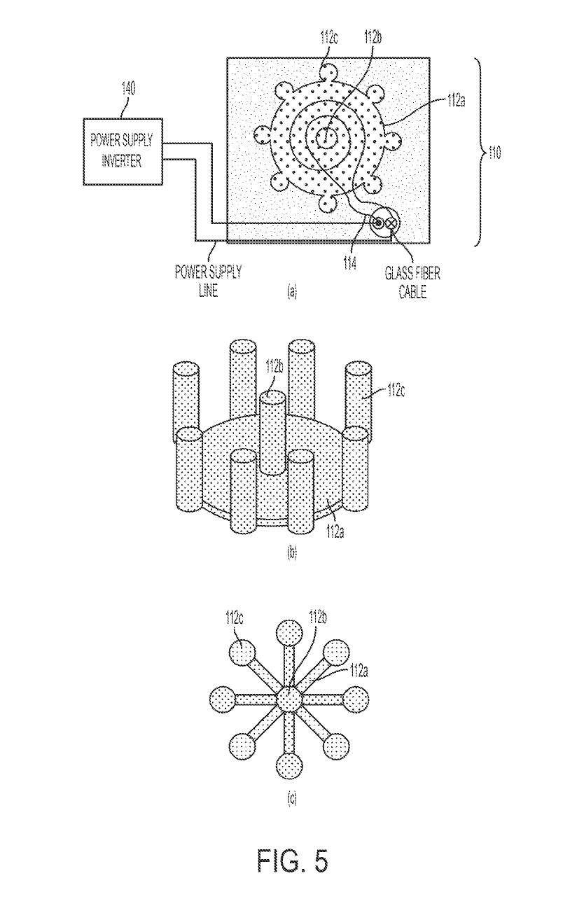

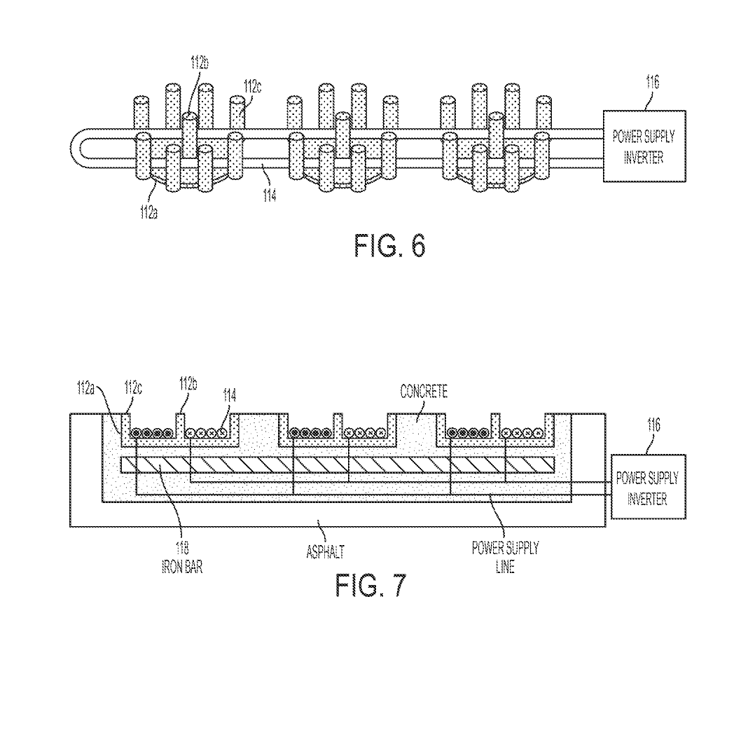

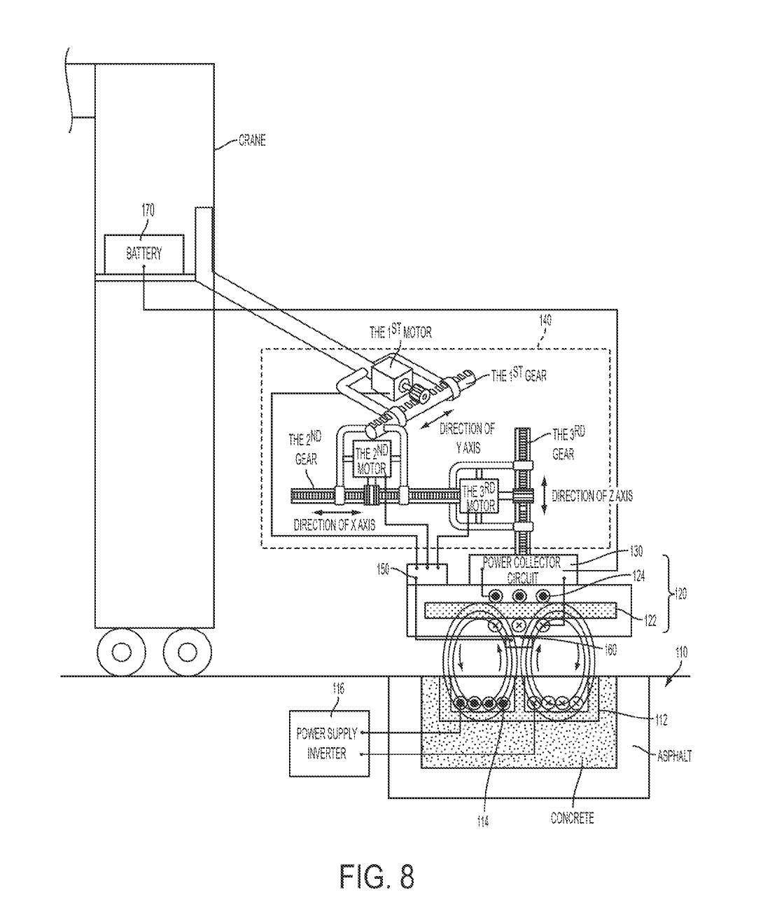

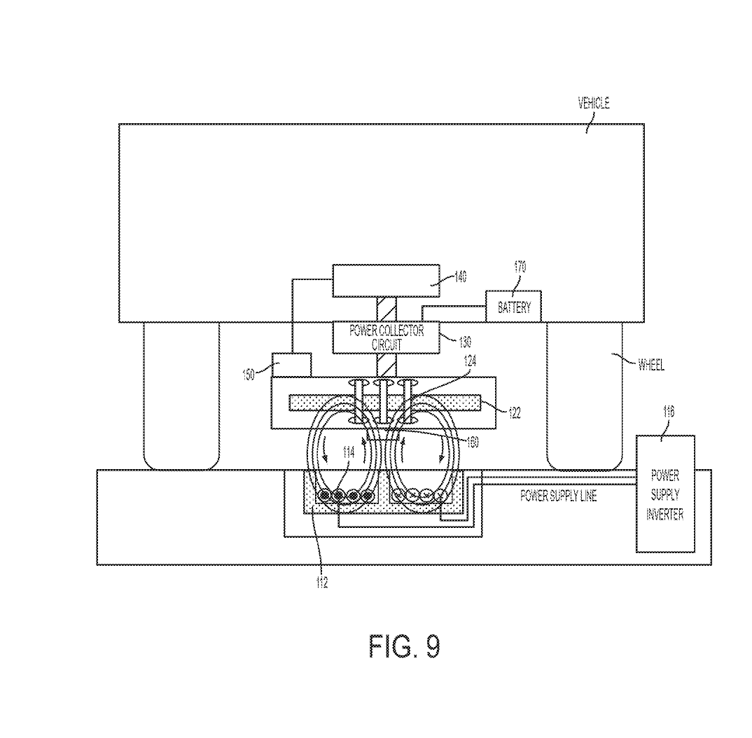

### TECHNICAL FIELD

Embodiments of the present invention relate to a non-contact power transmission device, a magnetic induction-type power supply device, a magnetic induction-type power collector, and a moving object using same. More particularly, embodiments of the present invention relate to a non-contact power transmission device, a magnetic induction-type power supply device, a magnetic induction-type power collector and moving object using same to provide convenience in charging with a non-contact mode so as to transmit power without mechanical contact with a power transmission device when charging batteries to drive moving equipment using electricity such as electric vehicles or cranes.

### DESCRIPTION OF RELATED ART

In general, in order to drive moving equipment using electricity such as electric vehicles or cranes, it is necessary to charge batteries installed in them. However, if a man or subsidiary charger connects wire for charging to moving equipment and charges it, it is not only inconvenient but also the man may get a shock in the course of holding the plug and connecting it to the equipment. Therefore, as the way of charging the batteries of moving equipment using wire for charging brings about user's inconvenience and risk of shock, an effective power transmission method to charge the batteries of moving vehicle wirelessly is required.

### DESCRIPTION OF THE INVENTION

### Technical Task

To solve this problem, the purpose of embodiments of the present invention is to provide convenience in charging batteries by charging them in a non-contact manner without mechanical contact with a power transmission device when the batteries of moving equipment using electricity such as electric vehicles or cranes should be charged.

### Means to Solve the Task

The first embodiment of the present invention to achieve aforementioned purpose provides a non-contact power transmission device comprising a magnetic induction-type power supply device and a magnetic induction-type power collector; said power supply device includes a power supply, a power supply core which provides a magnetic flux path, and at least one power supply unit which includes a power supply cable that is electrically connected to said power supply and winds around said power supply core; said power collector includes at least one power collector unit which receives power by magnetic coupling with said power supply unit and a power collector cable that winds around said power collector core, a power collector circuit which converts the power supplied by said power collector unit, a driving part which provides power to move said power collector unit, and a control part which controls the position and movement of said driving part.

Said control part may generate control signal and provide it to said driving part so as to place said power collector unit in a position of receiving maximum power from one of said power supply units.

Said driving part can move said power collector unit in the direction of the x-, y-, or z-axis which is perpendicular to said power collector unit according to said control signal.

Said power collector part may have an additional sensor that detects the location of said power collector unit.

Said sensor can act as a magnetic flux detecting sensor that measures the strength of magnetic flux generated from said power supply unit.

At least one of the said power supply units may be arranged widthwise and another one may be arranged lengthwise.

At least one of the said power supply units may be arranged in the form of matrix of M×N (M and N are natural numbers).

At least one of the said power supply units may be positioned in parallel with the ground.

At least one of the said power supply units may be buried in the ground while the top of it may be exposed for magnetic coupling with said power collector unit.

At least one of the said power supply units may be buried in concrete while the bottom of it may have reinforcement member installed to secure said power supply unit.

Said reinforcement member may be an iron bar.

Said power collector circuit may convert the output of said power collector unit to DC.

Said power collector part may include additional batteries to save the DC output of said power collector circuit.

Said power supply may be an inverter.

Said power supply core may include the central core having protrusions on the center portion and multiple peripheral cores arranged in all directions from the central core.

Said central core and said peripheral core may be connected through the holder section to which each of the bottom part of said central core and said peripheral core is commonly connected.

Said power supply cable may be arranged in the inside of said peripheral core while winding in multiple turns around said central core.

Said power supply cable may be installed in such a manner that electric currents flow in the left and right side of said central core, while the directions of electric currents flow of said left and right power supply cable may be in the opposite direction from each other.

The second embodiment of the present invention to achieve said purpose, for a power collector device that receives power from a power supply unit in a manner of magnetic induction, receives power by magnetic coupling with said power supply unit and provides a magnetic induction-type power collector device comprising a power collector core, a power collector unit having a power collector cable that winds around said power collector core, a power collector circuit to convert the output of said power collector unit, a driving part that provides power to move said power collector unit, and a control part to control the location and movement of said driving part.

The third embodiment of the present invention to achieve aforementioned purpose provides a magnetic induction-type power supply device which includes a power supply, a power supply core which provides a magnetic flux path, and at least one power supply unit which includes a power supply cable that is electrically connected to said power supply and winds around said power supply core, and at least one of the said power supply units is arranged widthwise and another one is arranged lengthwise.

Said sensor may have an additional distance sensor installed.

The fourth embodiment of the present invention to achieve aforementioned purpose provides a moving object including said power collector device.

### Effect of the Invention

As explained in the above, an embodiment of the present invention has an effect to provide convenience in charging batteries by enabling to charge batteries in a non-contact manner by transmitting power without mechanical contact with a power transmission device before driving moving equipment using electricity such as electric vehicles or cranes.

### BRIEF DESCRIPTION OF THE SEVERAL VIEW OF THE DRAWING

Drawing 1 shows a non-contact power transmission device (100) according to an embodiment of the present invention.

Drawing 2 shows a top view of the power supply device (100a) and the power collector (100b) of Drawing 1.

Drawing 3 shows a cross-sectional view of a power supply unit (110) and a power collector unit (120) when an embodiment is cut along the A-A′ line in Drawing 2.

Drawing 4 shows various shapes of a power collector core (122) and various forms in which a power collector cable (124) winds around the power collector core (122).

Drawing 5 shows a detail form of a power supply unit (110) buried in concrete.

Drawing 6 shows a case where a power supply cable (114) is installed in a different manner from Drawing 2.

Drawing 7 shows a case where reinforcement member is installed in the bottom of a power supply core (112).

Drawing 8 shows a moving object according to the first embodiment of the present invention with application of a power collector supporting device according to the first embodiment of the present invention to a crane.

Drawing 9 shows a moving object according to the second embodiment of the present invention with application of a power collector supporting device according to the first present embodiment of the present invention to an electric vehicle.

### THE BEST FORM FOR EMBODIMENT OF THE INVENTION

From now on, some of the embodiments of the present invention will be described in detail on reference to the attached drawings. Note that when reference symbols are tagged to the components of each drawing, same components have the same symbol as much as possible even thought they are displayed on different drawings. Also, if it is considered that elaboration of configuration or function may confuse the gist of the present invention, such elaboration would be omitted.

Also, such terms as ‘the first’, ‘the second’, ‘A’, ‘B’, ‘(a)’, or ‘(b)’ may be used in explaining the components of the present invention. However, such terms are only to distinguish the applicable component from others and not limited to the essence, sequence or order of the applicable component. If it is stated that a component is “linked to”, “combined with” or “connected to” another component, such a component may be directly linked or connected to such another component but it should be understood that still another component may be “linked to”, “combined with” or “connected to” each of the components.

Drawing 1 shows a non-contact power transmission device (100) according to the first embodiment of the present invention.

As illustrated in Drawing 1, a non-contact power transmission device (100) according to the first embodiment of the present invention comprises a power supply device (100a) which supplies power in a manner of magnetic induction and a power collector device (100b) which receives power in the same manner.

At this point, a power supply part (100a) includes at least one power supply unit (110) which comprises a power supply (116), a power supply core (112) which provides a magnetic flux path and a power supply cable (114) which is electrically connected to the power supply (116) and winds around the power supply core (112).

A power collector part (100b) receives power through magnetic coupling with a power supply unit (110) and comprises at least one power collector unit (120) which has a power collector core (122) and a power collector cable (124) that winds around the power collector core (122), a power collector circuit (130) which converts power supplied from the power collector unit (120), a driving part (140) which supplies power to move a power collector unit (120) and a control part (150) which controls the position and movement of the driving part (140). For convenience' sake, Drawing 1 shows only one power collector unit (120).

For convenience' sake, Drawing 1 shows only one power supply unit (110). The image of the power supply core (112), power supply cable (114), power collector core (122) and power collector cable (124) show a cross-sectional view cut along the A-A′ line in Drawing 2, as mentioned later.

At this point, a power collector part (100b) may have an additional sensor to detect the position of a power collector unit (120) and additional batteries (170) which store DC output of a power collector circuit (130).

Drawing 2 shows a top view of the power supply part (100a) and the power collector part (100b) of Drawing 1 and Drawing 3 shows a cross-sectional view of a power supply unit (110) and a power collector unit (120) when they are cut along the A-A′ line in Drawing 2. For convenience' sake, indications of a driving part (140), a control part (150) and a sensor (160) are omitted in Drawing 2.

At least one power supply unit (110) may be arranged widthwise and another one may be arranged lengthwise. Drawings 2 and 3 show the position relationship between a power supply part (100a) which has more than one (for example, n) power supply units (110) widthwise and lengthwise in the form of m×n (m and n are natural numbers) matrix and a power collector unit (120) comprising a power collector core (122) and a power collector cable (124) that winds around the power collector core (122).

At this point, a power supply unit (110) comprises a power supply core (112) which has holder section (112a), a central core having protrusions on the center portion of the holder section (112a) and a peripheral core (112c) having protrusions around the perimeter of the holder section (112a) and a power supply cable (114) that winds around the protruded central core (112b). Drawing 2 shows a case where a power supply cable (114) winds around the protruded central core (112b). Although in Drawing 2 it is illustrated that a power supply cable (114) winds at a certain distance from the protruded central core (112b), a power supply cable (114) actually can wind around the protruded central core (112b) closely to minimize magnetic resistance.

In addition, a power collector unit (120) may be located in the opposite direction from the protruding portion (112b, 112c) of a power supply core (112).

Meanwhile, at least one power supply unit (110) may be arranged in parallel with the ground and a power supply unit (110) may be buried in the ground in which case the top of a power supply unit (110) may be exposed for magnetic coupling with a power collector unit (120).

As shown in Drawings 2 and 3, a power supply unit (110) may be installed in the concrete filled over the asphalt (ground) and a car having a power collector unit (120) passes over the asphalt where a power supply part (100a) having multiple power supply units (110) is buried and stops to charge the batteries and charges by approaching the power collector unit (120) installed in the car to one of the power supply units (110).

A power collector unit (120) receives power through magnetic coupling with a power supply unit (110). That is, magnetic flux is generated in each of the power supply units (110) when power is supplied by a power supply inverter (116) which is used as a power supply. When a power collector unit (120) is approached to one of the power supply units (110), there is interlinkage in a power collector core (122) by the magnetic flux generated by the power supply unit and induced electromotive force is generated in a power collector cable (124) by interlinkage magnetic flux.

Induced electromotive force generated in a power collector cable (124) is converted to DC through a power collector circuit (130) comprising resonance capacitor, low pass filter and rectifier and charged in the battery (170) installed in a vehicle.

At this point, a power supply unit (110) may be buried in the road or installed on the surface of road, but the present invention is not limited to it. A power supply unit (110) may be installed in various positions such as wall or ceiling.

Meanwhile, a power collector core (122) may be installed so that the length direction of the power collector core (122) is perpendicular to the protruding direction of the protruding portion of a power supply core (112). A power collector core (122) also may have the protruding portion in the direction of a power supply unit (110).

Drawing 4 shows various shapes of a power collector core (122) and various forms in which a power collector cable (124) winds around the power collector core (122).

A power collector core (122) may be in a flat form as shown in (a) of Drawing 4 or have the protruding portion (122a) in the direction of a power supply unit (110) as shown in (b) and (c) of Drawing 4.

Meanwhile, a power collector cable (124) may wind around the flat portion of a power collector core (122) as shown in (a) and (b) of Drawing 4 or wind around the protruding portion (122a) as shown in (c) of Drawing 4.

Drawing 5 shows the form of a power supply unit (110) buried in concrete in detail.

Each of the power supply units (110) as shown in (a) of Drawing 5 may have a power supply core (112) as shown in (b) of Drawing 5. The form of the holder section (112a) of a power supply core (112) does not have to be circular but may be tetragonal or others. The form of the bottom of the holder section (112a) also does not have to be flat but may be various figures or of structure which connect between the roots of the peripheral protruding portion (112c). Also, as shown in (c) of Drawing 3, each power supply unit (110) is in a form that the holder section (112a) shoot out in all directions, like the spokes of a wheel, around the protruded central core (112a) and protruded peripheral cores (112c) are placed at the end parts of such a radial shape.

For reference, “the mark of ( ) and (x) shown in Drawings 1 through 4 (a) indicate the direction flow-out (x) and flow-in ( )” of electric currents at one point, and a power supply line and a power supply cable (114) connected from a power supply inverter (116) may be covered by the sheath made of glass fiber to protect the line or cable from external shock.

Also, a power supply core (112) may comprise a central core having the protruding center (112b) on the center and multiple peripheral cores (112c) arranged in radial positions from the central core (112b). The central core (112b) and the peripheral core (112c) may be connected to each other through the holder section (112a) to which the roots of the central core (112b) and the peripheral core (112c) are connected.

At this point, a power supply cable (114) may be arranged in the inside of a peripheral core (112b) while winding around a central core (112b) in multiple turns.

Drawing 6 illustrates a case where a power supply cable (114) is installed differently from Drawing 2. As shown in drawing 6, a power supply cable (114) does not wind directly around a central core (112b) of one holder section (112a) but wind the whole of a central core (112b) to another holder section (112a) at once. That is, a power supply cable (114) is installed such a manner that electric currents flow in the left and right side with respect to a central core (112b) while the directions of electric currents flowing in the left and the right power supply cable (114) of a central core (112b) may be opposite each other. Although Drawing 6 shows a case where there is one power supply cable (114), there could be multiple power supply cables (114).

Drawing 7 shows a case where reinforcement member is installed in the bottom of a power supply core (112). As shown in Drawing 7, a power supply unit (110) may be buried in concrete, reinforcement member may be installed in the bottom of a power supply unit (110) so that it would be securely maintained, and reinforcement member may be made of iron bar.

As shown in Drawing 7, iron bar (118) installed in the root of a power supply core (112) may be used to prevent a power supply unit (110) or a power supply core (112) from being damaged due to land subsidence. Anything that could support the weight loaded on a power supply unit (110) may be used as an iron bar (118) that is used here.

From now on, a detail explanation is followed with reference to Drawings 1 through 5.

As shown in Drawing 1, a sensor (160) may be installed in a power collector unit (120). The sensor may be located in the opposite direction from a power supply unit (110). At this point, a sensor (160) may be a magnetic flux detecting sensor which detects the presence and strength of magnetic flux but the present invention is not limited to such a sensor but accepts various sensors. In addition, instead of a single sensor, multiple sensors may be used for the components of a sensor (160).

A sensor (160) detects how much a power supply unit (110) approaches to a power collector unit (120) and generates detecting information. For example, a magnetic flux detecting sensor which measures the strength of magnetic flux generated by a power supply unit (110) may be used as a sensor (160). When a magnetic flux detecting sensor is used, the information about a power supply unit (110) that may be detected by a sensor (160) may be the strength of magnetic field generated by a power supply unit (110).

Induced electromotive force can be generated in a power collector cable (124) that winds around a power collector core (122) due to interlinkage of the magnetic flux generated in a power supply unit (110) with a power collector core (122) and the induced electromotive force can be converted to the source of power chargeable in the battery (170) through a power collector circuit (130).

A control part (150) receives the information generated by a sensor (160) about the approach of a power supply unit (110). A control part (150) generates control signal for the position where a power collector unit (120) could receive maximum power from one of the power supply units (110) and provides it to a driving part (140).

A control part (150) receives information about the approach of a power supply unit (110) and generates driving signal to control a power collector unit (120) to be placed in the location easy to receive power from the power supply unit (110). That is, it controls a power collector core (122) to be placed in the location of highest magnetic field of a power supply unit (110).

A control part (150) sends driving signal to a driving part (140) and controls the location of a power collector unit (120) by moving the actuator (for example, a gear shown in Drawing 1) in the driving part (140) using a driving device such as a motor. At this time, a control part (150) moves a power collector unit (120) in the direction of higher magnetic field detected by a sensor (160) in generating driving signal so as to move the location of a power collector unit (120) connected to the actuator and stops generating driving signal when the magnetic field does not increase anymore, so that a power collector unit (120) would be at home where charging is available. At this time, a driving part (140) may comprise an actuator which receives driving signal and places a power collector unit (120) in the direction of the x-, y- and z-axis and a driving device which drives the actuator according to driving signal.

For example, as shown in Drawing 1, a driving part (140) may include 3 motors and 3 gears and moves each motor (the 1^{st} motor, the 2^{nd} motor and the 3^{rd} motor) drive according to the signal generated by a control part (150) in the direction of up-down (the direction of the z-axis), left-right (the x-axis) and front-back (the y-axis), respectively, so as to move a power collector unit (120) to approach to the central portion where the magnetic field of a power supply unit (110) is highest. If a vehicle having a power collector part (110a) stops at the place where a power supply part (100a) is buried and is going to charge the battery, a control part (150) has the 3^{rd} gear driven by the 3^{rd} motor and goes down in the direction of the z-axis so that a power collector unit (120) would approach to a power supply unit (110). At this time, in controlling the 3^{rd} motor, by installing an additional distance sensor like a ultrasonic sensor which detects a clearance from a power supply unit (110) and detecting the distance from the power supply unit (110) in the direction of the z-axis, distance of approaching to the direction of the z-axis (up-down direction) can be controlled so as to set a desirable distance between a power collector unit (120) and a power supply unit (110). Like this, when the location of a power collector unit (120) in the direction of the z-axis is determined by the control of a control part (150), the control part (150) can control the locations of the direction of the x-axis and the y-axis. For reference, the directions of the x-, y-, and z-axis are perpendicular to each other.

A control part (150) generates driving signal and places a power collector unit (120) in the direction of the z-axis and generates driving signal so as to drive the 2^{nd} motor and moves the 2^{nd} gear to control the location of a power collector unit (120) in the direction of the x-axis. When controlling the position of a power collector unit (120) in the direction of the x-axis, a control part (150) detects the strength of magnetic field from a magnetic flux detecting sensor included in a sensor (160) and generates driving signal so that a power collector unit (120) could move in the 1^{st} direction, one of the directions of the x-axis and when the strength of magnetic field detected by a magnetic flux detecting sensor gets weaker, it generates driving signal so that a power collector unit (120) would move in the direction of the x-axis in opposite direction from the 1^{st} direction. A control part (150) generates driving signal so that a power collector unit (120) could move in the direction of the x-axis opposite from the 1^{st} direction and if the strength of magnetic field detected by a magnetic flux detecting sensor is getting stronger, it continues to generate driving signal to move a power collector unit (120) in the direction of the x-axis opposite from the 1^{st} direction, and at the moment on which the strength of magnetic field detected by a magnetic flux detecting sensor is getting weaker, it generates driving signal to stop the movement of a power collector unit (120) on the x-axis.

A control part (150) generates driving signal and places a power collector unit (120) in the direction of the z- and x-axis and controls the position of a power collector unit (120) in the direction of the y-axis by generating driving signal to move the 1^{st} motor and moving the 1^{st} gear. In controlling the position of a power collector unit (120) in the direction of the y-axis, a control part (150) detects the strength of magnetic field from a magnetic flux detecting sensor included in a sensor (160) and generates driving signal so that a power collector unit (120) would move in the 2^{nd} direction, one of the directions of the y-axis and if the strength of magnetic field detected from a magnetic flux detecting sensor is getting weaker, it generates driving signal so that a power collector unit (120) would move in the direction of the y-axis opposite from the 2^{nd} direction. A control part (150) generates driving signal so that a power collector unit (120) would move in the direction of the y-axis opposite from the 2^{nd} direction and if the strength of magnetic field from a magnetic flux detecting sensor is getting stronger, it continues to generate driving signal so that a power collector unit (120) would move in the direction of the y-axis opposite from the 2^{nd} direction, and at the moment on which the strength of magnetic field from a magnetic flux detecting sensor is getting weaker, it generates driving signal so that the movement of a power collector unit (120) on the y-axis would stop. Like this, a control part (150) may generate driving signal so that a driving part (140) could move the position of a power collector unit (120) with respect to the x-, y- and z-axis, respectively.

When a power collector unit (120) is placed close to the central portion of the highest magnetic field of a power supply unit (110) by the driving signal generated by a control part (150), induced electromotive force is generated in the power collector cable (124) in the power collector unit (120) by interlinkage of the magnetic field generated by a power supply unit (110) to a power collector unit (120) and the induced electromotive force can be converted to a chargeable state by a power collector circuit (130) and charged in the battery (170).

A magnetic induction-type power collector device according to an embodiment of the present invention receives power through magnetic coupling with a power supply unit (110), and comprises a power collector core (122), a power collector unit (120) having a power collector cable (124) that winds around the power collector core (122), a power collector circuit (130) which converts the output of the power collector unit (120), a driving part (140) which provides power to move a power collector unit (120), and a control part (150) which controls the position and movement of the driving part (140). At this point, a power collector device according to an embodiment of the present invention may have an additional sensor (160) to detect the position of a power collector unit (120) and an additional battery which stores DC output of a power collector circuit (130). Because matters on a power collector unit (120), a power collector circuit (130), a driving part (140), a sensor (160), and a battery (170) have been mentioned in the description of a non-contact power transmission device (100) according to an embodiment of the present invention, detailed explanation about them will be omitted.

A magnetic induction-type power supply device according to an embodiment of the present invention comprises a power supply (116), a power supply core (112) which provides a magnetic flux path and at least one power supply core (112) which is electrically connected to a power supply (116) and a power supply cable (116) that winds around a power supply core (112) and at least one power supply unit (110) and another one are arranged widthwise and lengthwise, respectively. Because matters on a power supply (116), a power supply core (112), and a power supply cable (100) have been mentioned in the description of a non-contact power transmission device (100) according to an embodiment of the present invention, detailed explanation about them will be omitted.

Drawing 8 shows a moving object according to an embodiment of the present invention with application of a power collector part (100b) according to an embodiment of the present invention to a crane, and Drawing 9 shows a moving object according to another embodiment of the present invention with application of a power collector device of an embodiment of the present invention to a electric vehicle.

As shown in Drawings 8 and 9, it is possible to drive a moving object (crane or electric vehicle) using induced electromotive force charged in a battery (170) which is induced to a power collector device according to an embodiment of the present invention due to magnetic flux generated by a power supply unit (110).

Meanwhile, although a moving object of the present invention is explained with an example of crane or electric vehicle in the present embodiment, the present invention is not limited to it but can be applied to various moving devices that move by driving an engine using a battery (170) and stop to charge the battery such as electric train, electric motorcycle and robot.

Note that all components of an embodiment of the present invention are united or operated in a unit does not necessarily mean that the present invention has to be limited to such an embodiment. That is, within the scope of the purpose of the present invention, all components may be selectively united to more than one and operate.

In addition, because unless otherwise specified contrarily, the abovementioned terms of “include”, “comprise” or “have” mean that the applicable component may be inherent, these terms should be interpreted to be able to include other components not to exclude them. Unless otherwise defined, all terms including technical or scientific terminologies have the same meaning as understood by those who have common knowledge in the technical field to which the present invention belongs. Terms generally used, like those defined in a dictionary, should be interpreted to be matched to the contextual meaning of related technology and unless clearly defined in the present invention, it should not be interpreted as ideal or excessively formal.

The abovementioned explanation is merely an illustration of the technical idea of the present invention, and those who have common knowledge of the technical field to which the present invention belongs could carry out various alterations and modifications within the scope not deviating from the essential characteristics of the present invention. Therefore, the embodiments of the present invention are not to limit but explain the technical idea of the present invention and such embodiments do not limit the scope of the technical idea of the present invention. The protection scope of the present invention should be interpreted by the following scope of claim and all the technical ideas within the scope equivalent thereto should be interpreted to be included in the extent of a right of the present invention.

### AVAILABILITY IN INDUSTRY

As mentioned above, the present invention is a useful invention which has an effect of providing convenience and safety in charging batteries to a moving object such as electric vehicle which stops to charge the batteries in a non-contact manner without mechanical contact with a power transmission device.

1. A non-contact power transmission device which comprises a magnetic induction-type power supply device and a magnetic induction-type power collector; said power supply device comprises a power supply, a power supply core which provides a magnetic flux path, and at least one power supply unit including a power supply cable that is electrically connected to said power supply and winds around said power supply core and said power collector receiving power through magnetic coupling with said power supply unit and comprising at least one power collector unit that has a power collector core and a power collector cable winding around said power collector core, a power collector circuit which converts the power supplied by said power collector unit, a driving part which provides power to move said power collector unit and a control part which controls the position and movement of said driving part.

2. The non-contact power transmission device as claim 1, wherein said control part generates control signal to place said power collector unit in a position to receive maximum power from one of said power supply units and provides the control signal to said driving part.

3. The non-contact power transmission device of claim 2, wherein said driving part moves said power collector unit in the direction of the x-, y-, and z-axis perpendicular to each other according to said control signal.

4. The non-contact power transmission device as claim 1, wherein said power collector has an additional sensor which detects the position of said power collector unit.

5. The non-contact power transmission device as claim 4, wherein said sensor is a magnetic flux detecting sensor which measures the strength of magnetic flux generated by said power supply unit.

6. The non-contact power transmission device as claim 1, wherein at least one of the said power supply units is arranged widthwise and another at least one is arranged lengthwise.

7. The non-contact power transmission device as claim 6, wherein at least one of the said power supply units is arranged in the form of M×N matrix (M and N are natural numbers).

8. The non-contact power transmission device as claim 1, wherein at least one of the said power supply units is arranged in parallel with the ground.

9. The non-contact power transmission device as claim 8, wherein at least one of the said power supply units is buried in the ground and the top of at least one of the supply power units is exposed for magnetic coupling with said power collector unit.

10. The non-contact power transmission device as claim 9, wherein at least one of the said power supply unit is buried in concrete and the bottom of said power supply unit has reinforcement member installed to secure said power supply unit.

11. The non-contact power transmission device as claim 10, wherein said reinforcement member is iron bar.

12. The non-contact power transmission device as claim 1, wherein said power collector circuit converts the output of said power collector unit to direct current.

13. The non-contact power transmission device as claim 12, wherein said power collector has an additional battery which stores DC output of said power collector circuit.

14. The non-contact power transmission device as claim 1, wherein said power supply is an inverter.

15. The non-contact power transmission device as claim 1, wherein said power supply core comprises:
a central core having protruding top in the central portion and multiple peripheral cores placed in radial positions from said central core.

16. The non-contact power transmission device as claim 15, wherein said central core and said peripheral core are connected to each other through the holder section to which the bottoms of said central core and said peripheral core are commonly connected.

17. The non-contact power transmission device as claim 16, wherein said power supply cable winds around said central core in multiple turns while being placed in the inside of said peripheral core.

18. The non-contact power transmission device as claim 16, wherein said power supply cable is installed in such a manner that it passes the left and the right side with respect to said central core while the directions of electric currents flowing in said left and right power supply cables are opposite each other.

19-36. (canceled)
